(19) United States
(12) Patent Application Publication
(10) Pub. No.: US 2021/0074775 A1
(43) Pub. Date: Mar. 11, 2021

(54) DIRECT VIEW DISPLAY DEVICE CONTAINING ORGANIC LIGHT EMITTING DIODE SUBPIXELS AND METHODS OF MAKING THE SAME

(71) Applicant: GLO AB, Lund (SE)

(72) Inventors: Timothy GALLAGHER, Los Altos Hills, CA (US); Brian KIM, Palisades Park, NJ (US); Fariba DANESH, Los Altos Hills, CA (US)

(21) Appl. No.: 16/567,451

(22) Filed: Sep. 11, 2019

(51) Int. Cl. H01L 27/32; H01L 51/52; H01L 27/28

(52) U.S. Cl. CPC H01L 27/3218; H01L 33/30; H01L 27/286; H01L 51/5271

(57) ABSTRACT

A light emitting device includes a first light emitting diode configured to emit light at a first peak wavelength, a second light emitting diode configured to emit light at a second peak wavelength that is different from the first peak wavelength, and a third light emitting diode including, from bottom to top, a lower electrode, an organic light emitting material portion, and an upper electrode, where the third light emitting diode is configured to emit light at a third peak wavelength that is different from the first and second peak wavelengths. A pattern definition layer which includes an opaque material covers at least a portion of the organic light emitting material portion and includes an opening overlying the organic light emitting material portion.

### FIELD

The present invention relates to monolithic multicolor display devices, and particularly to a direct view display device including pattern definition layers for organic light emitting subpixels and methods of fabricating the same.

### BACKGROUND

For light emitting devices, such as light emitting diodes (LED), the emission wavelength is determined by the band gap of the active region of the LED together with thickness determined confinement effects. Often the active region includes one or more bulk semiconductor layers or quantum wells (QWs). For III-nitride based LED devices, such as GaN based devices, the active region (e.g., bulk semiconductor layer or QW well layer) material is preferably ternary, such as InₓGa₁₋ₓN, where 0<x<1.

The band gap of such III-nitride is dependent on the amount of In incorporated in the active region. Higher indium incorporation will yield a smaller band gap and thus longer wavelength of the emitted light. As used herein, the term “wavelength” refers to the peak emission wavelength of the LED. It should be understood that a typical emission spectra of a semiconductor LED is a narrow band of wavelength centered around the peak wavelength.

However, incorporating sufficient indium into indium gallium nitride active region to generate light having the peak emission wavelength in the red spectral range is relatively difficult.

### SUMMARY

According to an aspect of the present disclosure, a light emitting device includes a first light emitting diode configured to emit light at a first peak wavelength, a second light emitting diode configured to emit light at a second peak wavelength that is different from the first peak wavelength, and a third light emitting diode including, from bottom to top, a lower electrode, an organic light emitting material portion, and an upper electrode, where the third light emitting diode is configured to emit light at a third peak wavelength that is different from the first and second peak wavelengths. A pattern definition layer which includes an opaque material covers at least a portion of the organic light emitting material portion and includes an opening overlying the organic light emitting material portion.

According to another aspect of the present disclosure, a method of forming a light emitting device comprises forming a first light emitting diode configured to emit light at a first peak wavelength; forming a second light emitting diode configured to emit light at a second peak wavelength that is different from the first peak wavelength; and forming a third light emitting diode which includes, from bottom to top, a lower electrode, an organic light emitting material portion, and an upper electrode and configured to emit light at a third peak wavelength that is different from the first and second peak wavelengths, and forming a pattern definition layer including an opaque material that covers at least a portion of the organic light emitting material portion, such that an opening is located over the organic light emitting material portion.

### BRIEF DESCRIPTION OF THE DRAWINGS

FIG. 1 is a top-down view of a direct view display device including an array of pixels according to the third embodiment of the present disclosure.

FIG. 2A is a plan view of a first exemplary structure after formation of a single crystalline buffer semiconductor layer and a n-doped compound semiconductor substrate layer on a growth substrate according to a first embodiment of the present disclosure. FIG. 2B is a vertical cross-sectional view along the vertical plane B-B′ of FIG. 2A.

FIG. 3A is a plan view of the first exemplary structure after formation of a first-type active region layer according to the first embodiment of the present disclosure.

FIG. 3B is a vertical cross-sectional view along the vertical plane B-B′ of FIG. 3A.

FIG. 4A is a plan view of the first exemplary structure after formation of a first masking layer and a second-type active region layer according to the first embodiment of the present disclosure.

FIG. 4B is a vertical cross-sectional view along the vertical plane B-B′ of FIG. 4A.

FIG. 5A is a plan view of the first exemplary structure after formation of a second masking layer and patterning the active region layers according to the first embodiment of the present disclosure.

FIG. 5B is a vertical cross-sectional view along the vertical plane B-B′ of FIG. 5A.

FIG. 6A is a plan view of the first exemplary structure after removing the masking layers according to the first embodiment of the present disclosure.

FIG. 6B is a vertical cross-sectional view along the vertical plane B-B′ of FIG. 6A.

FIG. 7A is a plan view of the first exemplary structure after depositing a continuous semiconductor junction layer and a transparent conductive layer according to the first embodiment of the present disclosure.

FIG. 7B is a vertical cross-sectional view along the vertical plane B-B′ of FIG. 7A.

FIG. 8A is a plan view of the first exemplary structure after patterning the transparent conductive layer and the continuous semiconductor junction layer according to the first embodiment of the present disclosure.

FIG. 8B is a vertical cross-sectional view along the vertical plane B-B′ of FIG. 8A.

FIG. 9A is a plan view of the first exemplary structure after formation of a third light emitting diode including, from bottom to top, a lower electrode, an organic light emitting material portion, and an upper electrode according to the first embodiment of the present disclosure.

FIG. 9B is a vertical cross-sectional view along the vertical plane B-B′ of FIG. 9A.

FIG. 10A is a plan view of the first exemplary structure after formation of an insulating cap layer and contact via structures according to the first embodiment of the present disclosure.

FIG. 10B is a vertical cross-sectional view along the vertical plane B-B′ of FIG. 10A.

FIG. 11A is a plan view of a first configuration of a second exemplary structure after formation of a lower electrode and an organic light emitting material portion according to the second embodiment of the present disclosure.

FIG. 11B is a vertical cross-sectional view along the vertical plane B-B′ of FIG. 11A.

FIG. 12A is a plan view of the first configuration of the second exemplary structure after formation of an emission-level dielectric material spacer according to the second embodiment of the present disclosure.

FIG. 12B is a vertical cross-sectional view along the vertical plane B-B′ of FIG. 12A.

FIG. 13A is a plan view of the first configuration of the second exemplary structure after formation of an upper electrode according to the second embodiment of the present disclosure.

FIG. 13B is a vertical cross-sectional view along the vertical plane B-B′ of FIG. 13A.

FIG. 14A is a plan view of the first configuration of the second exemplary structure after formation of an insulating cap layer and contact via structures according to the second embodiment of the present disclosure.

FIG. 14B is a vertical cross-sectional view along the vertical plane B-B′ of FIG. 14A.

FIG. 15A is a plan view of a second configuration of the second exemplary structure after formation of an insulating cap layer and contact via structures according to the second embodiment of the present disclosure.

FIG. 15B is a vertical cross-sectional view along the vertical plane B-B′ of FIG. 15A.

FIG. 16A is a plan view of a third configuration of the second exemplary structure after formation of an emission-level dielectric material spacer according to the second embodiment of the present disclosure.

FIG. 16B is a vertical cross-sectional view along the vertical plane B-B′ of FIG. 16A.

FIG. 17A is a plan view of the third configuration of the second exemplary structure after formation of an upper electrode according to the second embodiment of the present disclosure.

FIG. 17B is a vertical cross-sectional view along the vertical plane B-B′ of FIG. 17A.

FIG. 18A is a plan view of the third configuration of the second exemplary structure after formation of an insulating cap layer and contact via structures according to the second embodiment of the present disclosure.

FIG. 18B is a vertical cross-sectional view along the vertical plane B-B′ of FIG. 18A.

FIG. 19A is a plan view of a first configuration of a third exemplary structure after formation of a capping line according to the third embodiment of the present disclosure.

FIG. 19B is a vertical cross-sectional view along the vertical plane B-B′ of FIG. 19A.

FIG. 20A is a plan view of the first configuration of the third exemplary structure after formation of an insulating cap layer and contact via structures according to the third embodiment of the present disclosure.

FIG. 20B is a vertical cross-sectional view along the vertical plane B-B′ of FIG. 20A.

FIG. 21A is a plan view of a second configuration of the third exemplary structure after formation of an insulating cap layer and contact via structures according to the third embodiment of the present disclosure.

FIG. 21B is a vertical cross-sectional view along the vertical plane B-B′ of FIG. 21A.

FIG. 22A is a plan view of a third configuration of a third exemplary structure after formation of a capping line according to the third embodiment of the present disclosure.

FIG. 22B is a vertical cross-sectional view along the vertical plane B-B′ of FIG. 22A.

FIG. 23A is a plan view of the third configuration of the third exemplary structure after formation of an insulating cap layer and contact via structures according to the third embodiment of the present disclosure.

FIG. 23B is a vertical cross-sectional view along the vertical plane B-B′ of FIG. 23A.

FIG. 24A is a plan view of a fourth configuration of the third exemplary structure after formation of an insulating cap layer and contact via structures according to the third embodiment of the present disclosure.

FIG. 24B is a vertical cross-sectional view along the vertical plane B-B′ of FIG. 24A.

FIG. 25A is a plan view of a fifth configuration of the third exemplary structure after formation of an insulating cap layer and contact via structures according to the third embodiment of the present disclosure.

FIG. 25B is a vertical cross-sectional view along the vertical plane B-B′ of FIG. 25A.

### DETAILED DESCRIPTION

As discussed above, the present disclosure is directed to a direct view display device including pattern definition layers for organic light emitting subpixels and methods of fabricating the same, the various aspects of which are discussed herein in detail.

Simultaneous growth of several color LEDs in one step would be of high commercial interest, not only for RGB (Red Green Blue), YB (Yellow Blue) or YGB (Yellow Green Blue) combinations for white rendition of light (i.e., white light emitting LED based on combination of RGB, YB or YGB peak wavelength emission) or direct view multi-color display where at least one LED emitted light color is viewed directly by a human observer, but also high efficiency GB (Green Blue) since viable green phosphors and green LEDs based on other material systems have been hard to realize. In one embodiment, different color LEDs are simultaneously grown on the same substrate. In another embodiment, different color LEDs are grown sequentially on the same substrate or are grown on separate substrates and then attached to a common backplane to form a light emitting device, such as a direct view display device or another type of display device. As used herein, the term simultaneous growth in one step means that the corresponding layers or structures of different color emitting LEDs are grown in one step. Thus, for example, the nanostructure cores of different color emitting LEDs may be grown in the same first step, the active regions of different color emitting LEDs may be grown in the same second step and the junction forming elements or shells of different color emitting LEDs may be grown in the same third step.

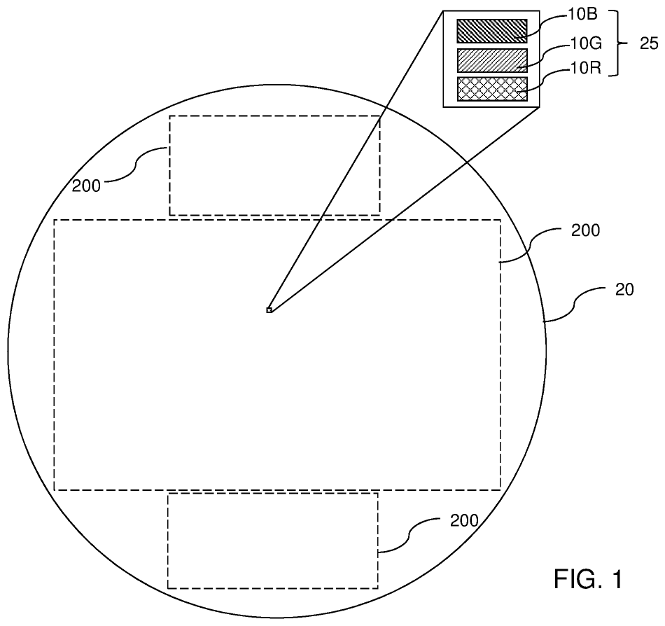

Referring to FIG. 1, direct view display devices 200 formed on a substrate 20 are illustrated. Each direct view display device 200 is a display device in which each pixel 25 includes at least one light source that generates light from within upon application of a suitable electrical bias. An array of pixels 25 can be fabricated directly on the substrate 20 by semiconductor fabrication methods without employing bonding of an additional substrate or transfer of dies such as light emitting diode dies. Each pixel 25 includes at least one first-type light emitting diode 10B (such as at least one blue-light-emitting diode) that emits light at a first peak wavelength (such as a peak wavelength in a range from 400 nm to 495 nm), at least one second-type light emitting diode 10B (such as at least one green-light-emitting diode, for example two green-light-emitting diodes) that emits light at a second peak wavelength (such as a peak wavelength in a range from 495 nm to 570 nm), and at least one third-type light emitting diode 10R (such as at least one red-light-emitting diode) that emits light at a third peak wavelength (such as a peak wavelength in a range from 600 nm to 700 nm). Each light emitting diode (10B, 10G, 10R) can have a planar structure in which each material layer is a planar material layer and each junction is a horizontal p-i-n or p-n junction located within a respective horizontal plane (i.e., a horizontal plane is parallel to the top surface of the substrate). There may be any suitable number of sub-pixels per pixel, such as three or more sub-pixels, for example four to six sub-pixel. For example, each pixel may contain one red light emitting sub-pixel, one blue light emitting sub-pixel and two green light emitting sub-pixels for example, for a total of four sub-pixels per pixel.

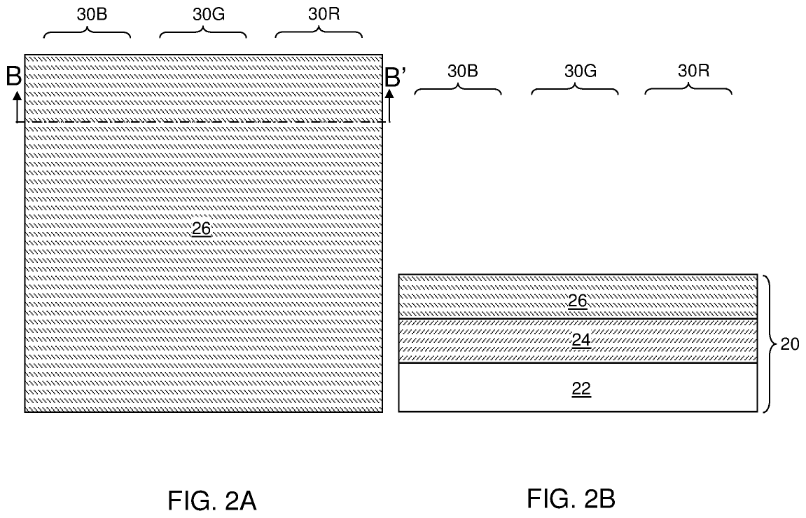

Referring to FIGS. 2A and 2B, a region of a substrate 20 corresponding to a single pixel area is illustrated. The substrate 20 can be provided by epitaxially growing a single crystalline buffer semiconductor layer 24 and an n-doped compound semiconductor substrate layer 26 on a top surface a growth substrate 22. The single pixel area (i.e., the area for forming a single pixel) can include a first light emitting region 30B (which may be, for example, a blue-light-emitting diode area) for building a first-type light emitting diode configured to emit light at a first peak wavelength, a second light emitting region 30G (which may be, for example, a green-light-emitting diode area) for building a second-type light emitting diode configured to emit light at a second peak wavelength that may be longer than the first peak wavelength, and a third light emitting region 30R (which may be, for example, a red-light-emitting diode area) for building a third-type light emitting diode configured to emit light at a third peak wavelength that may be longer than the second peak wavelength. The lateral extent of each light emitting region (30B, 30G, 30R) can be in a range from 100 nm to 50 microns (such as from 200 nm to 10 microns, including 500 nm to 1 micron), although lesser and greater dimensions may also be employed. The general shape of each light emitting region (30B, 30G, 30R) may be rectangular, circular, hexagonal, or of any two-dimensional curvilinear shape having a closed periphery.

The growth substrate 22 can include a single crystalline growth substrate material such as Al₂O₃ (sapphire) using either basal plane or r-plane growing surfaces, diamond, Si, Ge, GaN, AN, SiC in both wurtzite (a) and zincblende (β) forms, InN, GaP, GaAsP, GaAs, InP, ZnO, ZnS, and ZnSe. For example, the growth substrate 22 can include sapphire (i.e., single crystalline aluminum oxide) with a suitable surface orientation. The growth substrate 22 may comprise a patterned sapphire substrate (PSS) having a flat growth surface or a patterned (e.g., rough) growth surface. Bumps, dimples, and/or angled cuts may, or may not, be provided on the top surface of the growth substrate 22 to facilitate epitaxial growth of the single crystalline compound semiconductor material of the single crystalline buffer semiconductor layer 24, to facilitate separation of the single crystalline buffer semiconductor layer 24 from the growth substrate 22 in a subsequent separation process.

The single crystalline buffer semiconductor layer 24 includes a single crystalline compound semiconductor material such as a III-V compound semiconductor material, for example a Group III-nitride compound semiconductor material. The deposition process for forming the single crystalline buffer semiconductor layer 24 can employ any of metalorganic vapor phase epitaxy (MOVPE), molecular beam epitaxy (MBE), hydride vapor phase epitaxy (HVPE), liquid phase epitaxy (LPE), metal-organic molecular beam epitaxy (MOMBE), and atomic layer deposition (ALD). The single crystalline buffer semiconductor layer 24 can have a constant or a graded composition such that the composition of the single crystalline buffer semiconductor layer 24 at the interface with the growth substrate 22 provides a substantial lattice matching with the two-dimensional lattice structure of the top surface of the growth substrate 22. The composition of the single crystalline buffer semiconductor layer 24 can be gradually changed during the deposition process. If the growth substrate 22 includes patterned sapphire, then the bottom surface of the single crystalline buffer semiconductor layer 24 may be a patterned (i.e., rough) surface.

The single crystalline buffer semiconductor layer 24 may have a compositionally graded single crystalline semiconductor material that is epitaxially aligned to the single crystalline growth substrate material of the growth substrate 22. The composition of the single crystalline buffer semiconductor layer 24 can gradually change with thickness so that the lattice constant of the topmost portion of the single crystalline buffer semiconductor layer 24 matches the lattice constant of a compound semiconductor material (such as an n-doped GaN material) to be grown on top of the single crystalline buffer semiconductor layer 24 to provide an n-doped compound semiconductor substrate layer 26.

In one embodiment, the materials that can be employed for a bottom portion of the single crystalline buffer semiconductor layer 24 can be, for example, Ga_{1-w-x}In_{w}AlₓN in which w and x range between zero and less than one, and can be zero (i.e., GaN) and are selected to match the lattice constant of the top surface of the growth substrate 22. Optionally, As and/or P may also be included in the material for the bottom portion of the single crystalline buffer semiconductor layer 24, in which case the bottom portion of the single crystalline buffer semiconductor layer 24 can include Ga_{1-w-x}In_{w}AlₓN_{1-x-z}As_{y}P_{z} in which y and z between zero and less than one, that matches the lattice constant of the top surface of the growth substrate 22. The materials that can be employed for an top portion of the single crystalline buffer semiconductor layer 24 include, but are not limited to, III-V compound materials, including III-nitride materials, such as gallium nitride (GaN), aluminum nitride (AlN), indium nitride (InN), gallium aluminum nitride, and gallium indium nitride, as well as other III-V materials, such as gallium phosphide (GaP), gallium arsenide (GaAs), gallium antimonide (GaSb), Indium phosphide (InP), indium arsenide (InAs), and indium antimonide (InSb). The composition of the single crystalline buffer semiconductor layer 24 can gradually change between the bottom portion of the single crystalline buffer semiconductor layer 24 and the top portion of single crystalline buffer semiconductor layer 24 such that dislocations caused by a gradual lattice parameter change along the growth direction (vertical direction) does not propagate to the top surface of the single crystalline buffer semiconductor layer 24. In one embodiment, a thin bottom portion of the single crystalline buffer semiconductor layer 24 may be undoped or doped at a low concentration of silicon.

A high quality single crystalline surface with low defect density can be provided at the top surface of the single crystalline buffer semiconductor layer 24. Optionally, the top surface of the single crystalline buffer semiconductor layer 24 may be planarized to provide a planar top surface, for example, by chemical mechanical planarization. A suitable surface clean process can be performed after the planarization process to remove contaminants from the top surface of the single crystalline buffer semiconductor layer 24. The average thickness of the single crystalline buffer semiconductor layer 24 may be in a range from 0.1 microns to 3 microns, such as from 0.2 microns to 1 micron, although lesser and greater thicknesses can also be employed.

An n-doped compound semiconductor substrate layer 26 is subsequently formed directly on the top surface of the single crystalline buffer semiconductor layer 24. The n-doped compound semiconductor substrate layer 26 can be formed as a continuous material layer having a uniform thickness over the entire top surface of the single crystalline buffer semiconductor layer 24. The n-doped compound semiconductor substrate layer 26 includes an n-doped compound semiconductor material. The n-doped compound semiconductor substrate layer 26 can be lattice matched with the single crystalline compound semiconductor material of the top portion of the single crystalline buffer semiconductor layer 24. The n-doped compound semiconductor substrate layer 26 may, or may not, include the same compound semiconductor material as the top portion of the single crystalline buffer semiconductor layer 24. In one embodiment, the n-doped compound semiconductor substrate layer 26 can include an n-doped direct band gap compound semiconductor material. In one embodiment, the n-doped compound semiconductor substrate layer 26 can include n-doped gallium nitride (GaN), indium gallium nitride (InGaN) or other III-V semiconductor materials, such as gallium phosphide or its ternary or quarternary compounds. The deposition process for forming the n-doped compound semiconductor substrate layer 26 can employ any of metalorganic vapor phase epitaxy (MOVPE), molecular beam epitaxy (MBE), hydride vapor phase epitaxy (HVPE), liquid phase epitaxy (LPE), metal-organic molecular beam epitaxy (MOMBE), and atomic layer deposition (ALD).

The n-doped compound semiconductor substrate layer 26 is epitaxially aligned to the compositionally graded single crystalline semiconductor material of the single crystalline buffer semiconductor layer 24. The thickness of the n-doped compound semiconductor substrate layer 26 can be in a range from 3 microns to 10 microns, although lesser and greater thicknesses can also be employed. The growth substrate 22, the single crystalline buffer semiconductor layer 24, and the n-doped compound semiconductor substrate layer 26 collectively comprise a substrate 20.

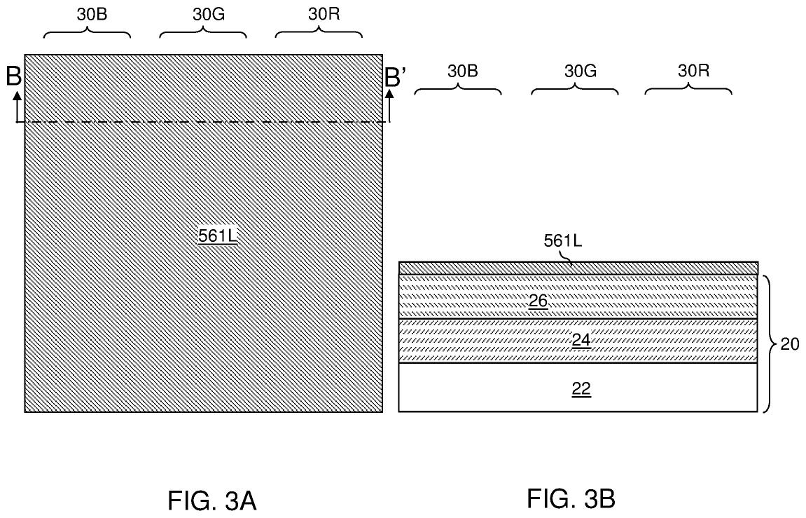

Referring to FIGS. 3A and 3B, a first-type active region layer 561L can be formed over the n-doped compound semiconductor substrate layer 26, which is a semiconductor material layer. The first-type active region layer 561L can be formed by at least one selective epitaxy process. The first-type active region layer 561L includes at least one epitaxial semiconductor material layer that is configured to emit light at a first peak wavelength upon application of electrical bias thereacross. In one embodiment, the first-type active region layer 561L can be configured to emit light at a first peak wavelength in a range from 400 nm to 495 nm (e.g., blue light). In one embodiment, the first-type active region layer 561L can have an InₓGa₁₋ₓN layer, wherein x is a real number between 0 and 1.

The first-type active region layer 561L can include a bulk or quasi-bulk semiconductor layer, such as the above described indium gallium nitride layer, which is intrinsic or lightly doped. A quasi-bulk semiconductor layer is a thin layer (e.g., having a thickness of 100 nm or less) which is not a quantum well layer (i.e., which is not located between two barrier layers). Alternatively, the first-type active region layer 561L can include a single quantum well or multiple quantum wells. In one embodiment, the first-type active region layer 561L can consist essentially of Ga atoms, In atoms, and N atoms (e.g., one or more InGaN well regions with the same or different indium content in different regions) located between GaN, InGaN or AlGaN barrier layers with higher band gaps. The first-type active region layer 561L is formed as a planar layer having a uniform thickness, which can be in a range from 5 nm to 30 nm, although lesser and greater thicknesses can also be employed. The first-type active region layer 561L can be formed as a single crystalline doped semiconductor material layer in epitaxial alignment with the single crystalline semiconductor material of the n-doped compound semiconductor substrate layer 26.

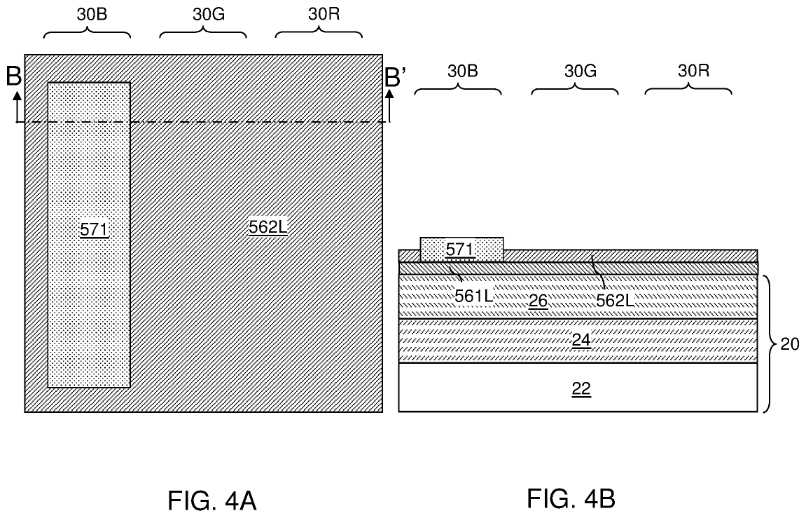

Referring to FIGS. 4A and 4B, a first masking layer 571 can be formed on a portion of the first-type active region layer 561L in the first light emitting region 30B. The first masking layer 571 can include a dielectric material that suppresses nucleation of a compound semiconductor material thereupon. For example, the first masking layer 571 can include silicon nitride or silicon oxide. The thickness of the first masking layer 571 can be in a range from 6 nm to 45 nm, and can be in a range from 100% to 150% of a second-type active region layer to be subsequently formed. The first masking layer 571 can be deposited as a blanket film (i.e., an unpatterned film), and can be patterned to cover the area of the first light emitting region 30B, for example, by a combination of lithographic methods and an etch process that etches the material of the first masking layer 571 selective to the semiconductor material of the first-type active region layer 561L. Overetch into the first-type active region layer 561L is minimized to avoid damage to the single crystalline structure of the first-type active region layer 561L.

A second-type active region layer 562L can be formed on the physically exposed surface of the first-type active region layer 561L. The second-type active region layer 562L can have the same composition as the second-type active region 462 described above, and can be formed employing the same deposition method as the deposition method employed to form the second-type active regions 462. The second-type active region layer 562L does not nucleate on physically exposed surfaces of the first masking layer 571 because the dielectric material of the first masking layer 571 suppresses nucleation of any compound semiconductor material thereupon.

The second-type active region layer 562L is formed as a planar layer having a uniform thickness, which can be in a range from 5 nm to 30 nm, although lesser and greater thicknesses can also be employed. The second-type active region layer 562L can be formed as a single crystalline doped semiconductor material layer in epitaxial alignment with the single crystalline semiconductor material of the first-type active region layer 561L. The second-type active region layer 562L can be formed in the same manner as the first-type active region layer 561L with a modification in material composition such that the second-type active region layer 562L is configured to emit light at a second peak wavelength upon application of electrical bias thereacross. The second peak wavelength can be longer than the first peak wavelength, and can be in a range from 495 nm to 570 nm (e.g., green light).

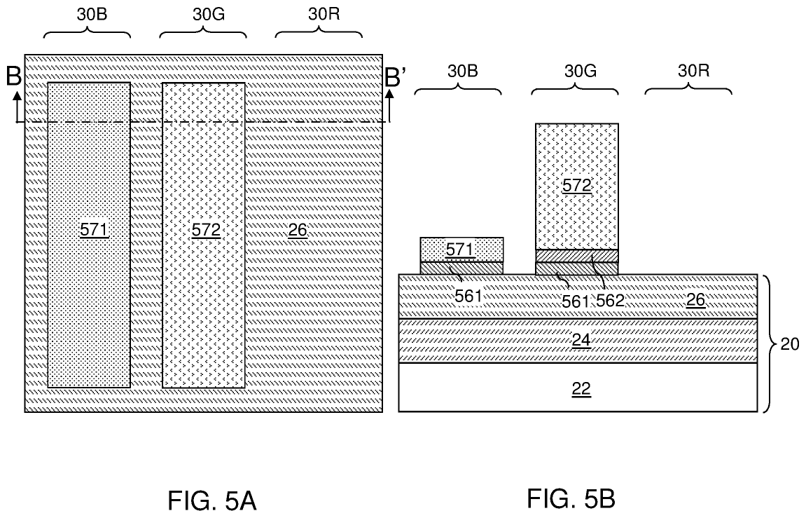

Referring to FIGS. 5A and 5B, a second masking layer 572 can be formed on a portion of the second-type active region layer 562L in the second light emitting region 30G. The second masking layer 572 can include a lithographically patterned photoresist layer. Alternatively, the second masking layer 572 can have the same composition as, and substantially the same thickness as, the first masking layer 571. In this case, the second masking layer 572 can be deposited as a blanket film (i.e., an unpatterned film), and can be patterned to cover the area of the second light emitting region 30B, for example, by a combination of lithographic methods and an etch process that etches the material of the second masking layer 572 selective to the semiconductor material of the second-type active region layer 562L.

Portions of the first-type active region layer 561L and the second-type active region layer 562L that are not masked by the first masking layer 571 or the second masking layer 572 can be subsequently etched by an etch process. The etch process include an anisotropic etch process or an isotropic etch process. The etch process etches the materials of the second-type active region layer 562L and the first-type active region layer 561L selective to the materials of the first and second masking layers (571, 572). A top surface of the n-doped compound semiconductor substrate layer 26 can be physically exposed around areas covered by the first and second masking layers (571, 572). Each remaining portion of the first-type active region layer 561L constitutes an instance of a first-type active region 561. The instance of the first-type active region 561 in the first light emitting region 30B is herein referred to as a first instance of the first-type active region 561. The instance of the first-type active region 561 in the second light emitting region 30G is herein referred to as a second instance of the first-type active region 561. Each remaining portion of the second-type active region layer 562L constitutes an instance of a second-type active region 562. Excess low-crystalline-quality growth may occur at the edges of the second-type active region layer 562L contacting the first masking layer 571. Such edge portions of the second-type active region layer 562L can be removed during the etching step that patterns the active regions (561, 562).

A first instance of the first-type active region 561 is formed over the n-doped compound semiconductor substrate layer 26 in the first light emitting region 30B. A stack of a second instance of the first-type active region 561 and an instance of the second-type active region 562 is formed over the n-doped compound semiconductor substrate layer 26 in the second light emitting region 30G. A top surface of the n-doped compound semiconductor substrate layer 26 is physically exposed in the third light emitting region 30R.

Each instance of the first-type active region 561 can comprise indium gallium nitride active regions, each instance of the second-type active region 562 can comprise indium gallium nitride active regions having a higher indium concentration than the first-type active regions 561. Each instance of the first-type active region 561 and each instance of the second-type active region 562 can be single crystalline and epitaxially aligned to one another. In some embodiments, the first-type active regions 561 can comprise a bulk or quasi-bulk InₓGa₁₋ₓ N layer or one or more quantum wells having GaN or AlGaN barrier layers and an InₓGa₁₋ₓ N well layer, wherein x is a real number between 0 and 1. The second-type active regions 562 can comprise a bulk or quasi-bulk In_{y}Ga_{1-y} N layer or one or more quantum wells having GaN or AlGaN barrier layers and an In_{y}Ga_{1-y} N well layer, wherein y is a real number between 0 and 1, and is greater than x.

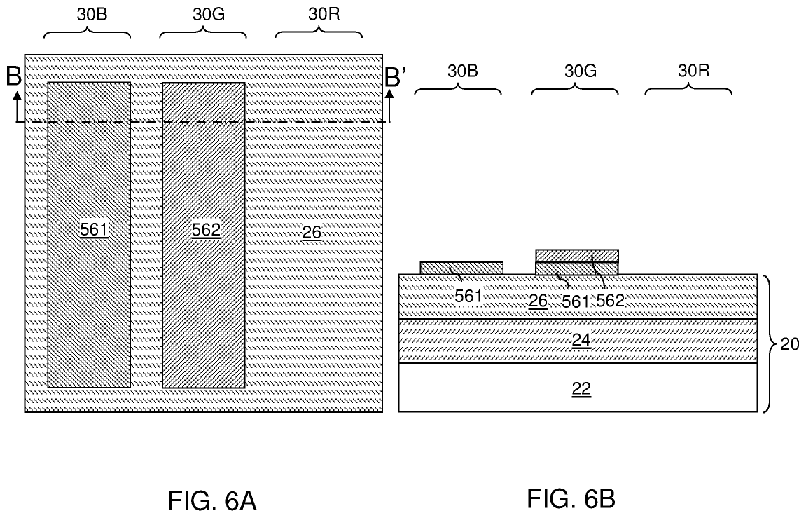

Referring to FIGS. 6A and 6B, the masking layers (571, 572) can be removed selective to the semiconductor materials of the active regions (561, 562) and the n-doped compound semiconductor substrate layer 26. For example, if the masking layers (571, 572) include silicon oxide, a wet etch employing hydrofluoric acid can be employed to remove the masking layers (571, 572). If the masking layers (571, 572) include silicon nitride, a wet etch employing phosphoric acid or a mixture of hydrofluoric acid and ethylene glycol can be employed to remove the masking layers (571, 572). If the second masking layer 572 includes a patterned photoresist material, an ashing process can be employed to remove the second masking layer 572.

In an alternative embodiment, patterned lift-off layers may be used in lieu of the masking layers (571, 572). In this case, a first patterned lift-off layer covering all areas other than the first light emitting region 30B and the second light emitting region 30G can be formed prior to deposition of the first-type active region layer 561L, and a second lift-off layer covering the first light emitting region 30B can be formed prior to deposition of the second-type active region layer 562L. The patterned lift-off layers can be subsequently removed to provide the first-type active regions 561 and the second-type active regions 562. Optionally, another patterning mask layer may be applied and patterned to cover center regions of the active regions (561, 562), and an etch process can be performed to remove unmasked peripheral portions of the active regions (561, 562) having lower crystalline quality, thereby leaving only highly crystalline material portions for the active regions (561, 562).

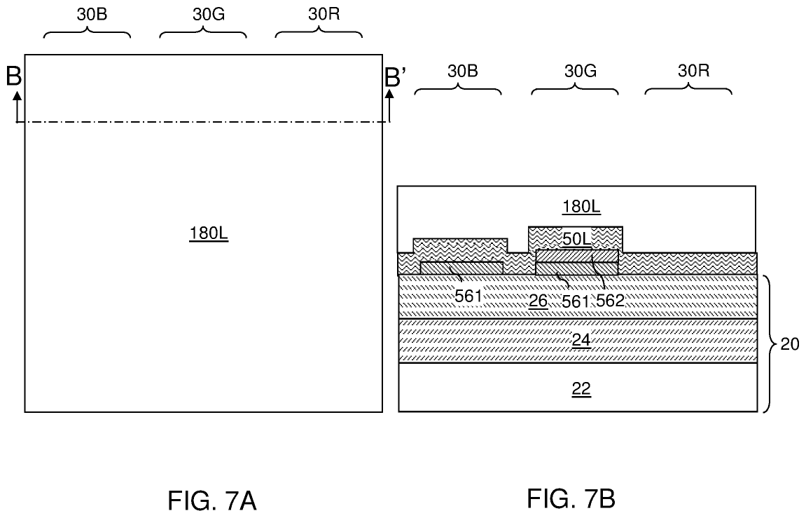

Referring to FIGS. 7A and 7B, a continuous semiconductor junction layer 50L can be deposited on the physically exposed top surfaces of the active regions (561, 562) formed by the etching or the lift off method described above. As used herein, a “semiconductor junction layer” refers to a doped semiconductor material layer having a p-type doping or an n-type doping and forms one side of a p-n or p-i-n junction. If the active regions (561, 562) include an intrinsic semiconductor material, then the semiconductor junction layer forms a p-i-n junction with a semiconductor layer of opposite conductivity type located on the opposite side of the active region. If the active regions (561, 562) comprise an n-type doped semiconductor material, then the active regions (561, 562) and the semiconductor junction layer form a p-n junction. The continuous semiconductor junction layer 50L can include a p-doped semiconductor material. For example, the continuous semiconductor junction layer 50L can include p-doped GaN and/or p-doped AlGaN. In one embodiment, the continuous semiconductor junction layer 50L can be formed by a semiconductor deposition process that grows a single crystalline p-doped semiconductor material from the physically exposed surfaces of the active regions (561, 562) with epitaxial alignment to the single crystalline materials of the active regions (561, 562). In one embodiment, the continuous semiconductor junction layer 50L may comprise plural sub-shells, such as p-GaN and p-AlGaN subshells. The thickness of the continuous semiconductor junction layer 50L can be in a range from 30 nm to 300 nm, although lesser and greater thicknesses can also be employed.

A continuous transparent conductive layer 180L can be deposited directly on the frontside surface of the continuous semiconductor junction layer 50L. The continuous transparent conductive layer 180L includes a transparent conductive oxide material such as a material selected from doped zinc oxide, indium tin oxide, aluminum zinc oxide (AZO), cadmium tin oxide (Cd₂SnO₄), zinc stannate (Zn₂SnO₄), and doped titanium dioxide (TiO₂). Exemplary doped zinc oxide materials include boron-doped zinc oxide, fluorine doped zinc oxide, gallium doped zinc oxide, and aluminum doped zinc oxide. The thickness of the continuous transparent conductive layer 180L can be in a range from 50 nm to 1 micron, such as from 100 nm to 600 nm, although lesser and greater thicknesses can also be employed.

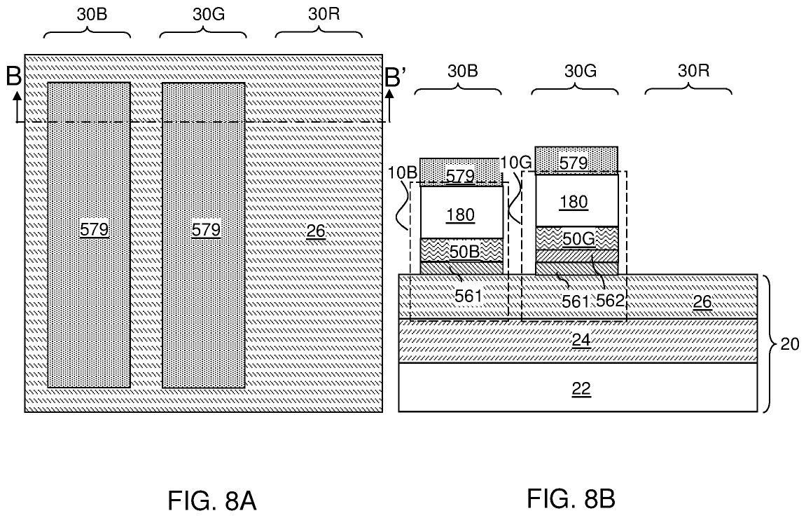

Referring to FIGS. 8A and 8B, a patterned masking layer 579 is formed over the continuous transparent conductive layer 180L to cover areas inside each periphery of the first-type active regions 561. In one embodiment, the patterned masking layer 579 can include a lithographically patterned photoresist layer. In one embodiment, each periphery of discrete portions of the patterned masking layer 579 can be laterally offset inward from a periphery of a respective underlying first-type active region 561. Unmasked portions of the continuous transparent conductive layer 180L, the continuous semiconductor junction layer 50L, the second-type active region 562, and the first-type active regions 561 can be removed by an etch process such as an anisotropic etch process. Each remaining portion of the continuous transparent conductive layer 180L constitutes a transparent conductive layer 180. A remaining portion of the continuous semiconductor junction layer 50L in the first light emitting region 30B is herein referred to as a first semiconductor junction layer 50B, and a remaining portion of the continuous semiconductor junction layer SOL in the second light emitting region 30G is herein referred to as a second semiconductor junction layer 50G. Each of the active regions (561, 562) may be laterally trimmed by the etch process. A vertical stack including the first instance of the first-type active region 561, the first semiconductor junction layer 50B, an overlying transparent conductive layer 180, and an underlying portion of the n-doped compound semiconductor substrate layer 26 constitutes a first light emitting diode 10B that can emit light at the first peak wavelength. A vertical stack including the second instance of the first-type active region 561, the second-type active region 562, the second semiconductor junction layer 50G, an overlying transparent conductive layer 180, and an underlying portion of the n-doped compound semiconductor substrate layer 26 constitutes a second light emitting diode 10G. The material composition of the active region in contact with a semiconductor junction layer determines the peak wavelength of light emitted from each light emitting diode. Thus, the second light emitting diode 10G is configured to emit light at the second peak wavelength.

Generally, a light emitting device of the embodiments of the present disclosure can include at least one pixel. A first light emitting diode 10B in each pixel can include a first stack containing a first instance of a first-type active region 561 that is configured to emit light at the first peak wavelength, and the second light emitting diode 10G in each pixel can include a second stack containing a second instance of the first-type active region 561 and a second-type active region 562 having a different composition than the first-type active region 561. The second-type active region 562 is configured to emit light at the second peak wavelength that is different from the first peak wavelength. The first exemplary light emitting device of the present disclosure can include a n-doped compound semiconductor substrate layer 26. Each first instance of the first-type active region 561 of the first stack of the at least one pixel can be formed directly on the n-doped compound semiconductor substrate layer 26, and each second instance of the first-type active region 561 of the second stack of the at least one pixel is formed directly on the n-doped compound semiconductor substrate layer 26. Each first instance of the first-type active region 561 of the first stack, each second instance of the first-type active region 561 of the second stack, and each second-type active region 562 of the at least one pixel includes a respective single crystalline doped semiconductor material that is epitaxially aligned to the n-doped compound semiconductor substrate layer 26.

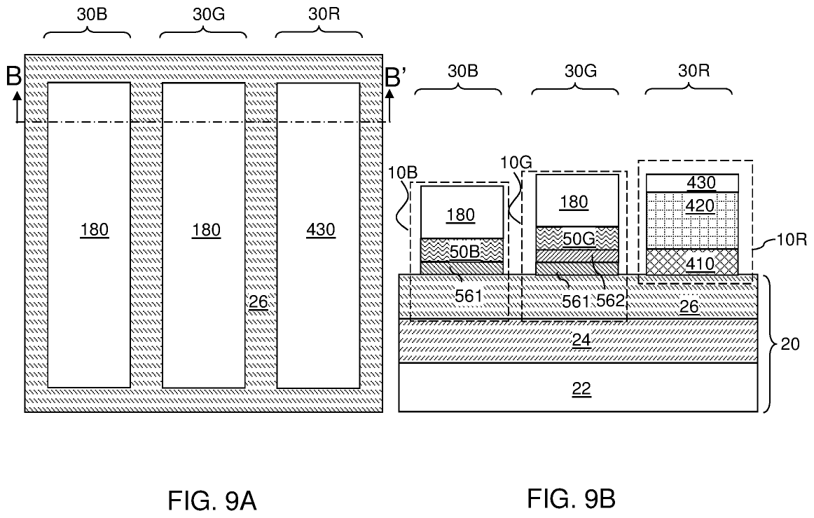

Referring to FIGS. 9A and 9B, a third light emitting diode 10R is formed within the third light emitting region 30R of each pixel. According to an aspect of the present disclosure, the third light emitting diode 10R can comprise an organic light emitting diode, which can include, for example, a lower electrode 410, an organic light emitting material portion 420, and an upper electrode 430. In one embodiment, the organic light emitting diode may be a red emitting OLED. The organic light emitting material portion 420 may contain one or more organic light emitting layers, such as polymer and/or small molecule semiconductor light emitting layers. The polymer semiconductor electroluminescent layers may comprise undoped polymers (e.g., derivatives of poly(p-phenylene vinylene) (PPV), poly(naphthalene vinylene) or polyfluorine) or doped polymers (e.g., poly(N-vinylcarbazole) host material with organometallic complex (e.g., platinum or iridium complex) dopant which use electrophosphorescence to convert electrical energy into light). In contrast, the first light emitting diode 10B and the second light emitting diode 10G in each pixel can be inorganic light emitting diodes that include inorganic Group IV, Group III-V or Group II-V semiconductor light emitting materials. For example, gallium nitride, indium gallium nitride or aluminum gallium nitride may be used as the light emitting materials.

The third light emitting diode 10R of each pixel can be formed by depositing a material layer stack including, from bottom to top, a metallic material layer (which is also referred to as a cathode material layer), an organic light emitting material layer, and a transparent conductive material layer (which is also referred to as an anode material layer) over the top surface of the n-doped compound semiconductor substrate layer 26, and by patterning the material layer stack employing a combination of a lithographic patterning process and an etch process (which may employ an anisotropic etch process or an isotropic etch process). Specifically, portions of the material layer stack outside the area of the third light emitting region 30R can be removed. The remaining portion of the material layer stack that remains within the area of the third light emitting region 30R constitutes the third light emitting diode 10R. The metallic material layer can include a conductive metal nitride material such as TiN, TaN, and/or WN. The transparent conductive material layer can include any material that can be employed for the transparent conductive layer 180.

Alternatively, a lift-off mask can be applied and patterned over the n-doped compound semiconductor substrate layer 26 to provide an opening within the area of the third light emitting region 30R. A material layer stack including, from bottom to top, a first metallic material layer, an organic light emitting material layer, and a second metallic material layer can be deposited within the opening in the lift-off mask by a respective conformal or non-conformal deposition process. Portions of the material layer stack overlying the lift-off mask can be removed by lifting off the lift-off mask from the areas outside the third light emitting region 30R.

Generally, the third light emitting diode 10R can include a third stack. The third stack includes, from bottom to top, a lower electrode 410, an organic light emitting material portion 420, and an upper electrode 430. The third stack can be configured to emit light at a third peak wavelength that is different from the first and second peak wavelengths. The upper electrode 430 includes an optically transparent material. The lower electrode 410 and the organic light emitting material portion 420 may be patterned employing a same anisotropic etch process. In this case, the lower electrode 410 and the organic light emitting material portion 420 can have vertically coincident sidewalls. As used herein, a first sidewall and a second sidewall are “vertically coincident” if the second sidewall overlies or underlies the first sidewall and if a vertical plane that includes the first sidewall and the second sidewall exists. In one embodiment, each lower electrode 410 of the third stack of the at least one pixel can be formed directly on the n-doped compound semiconductor substrate layer 26.

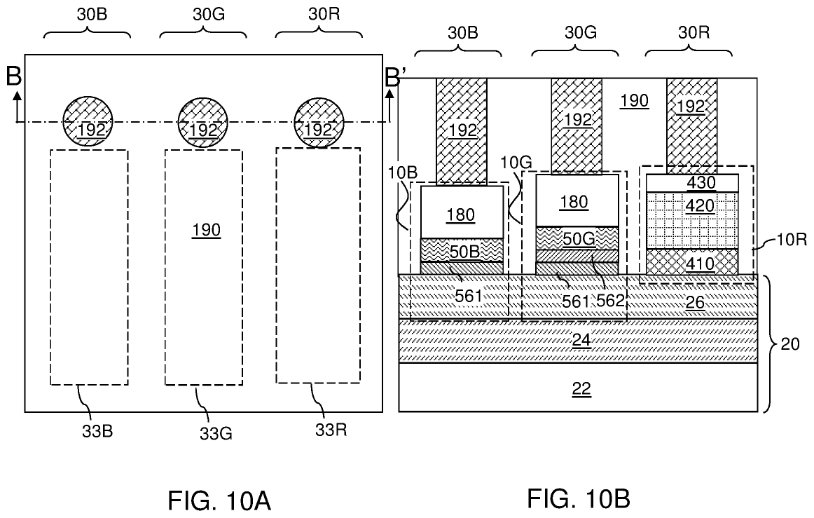

Referring to FIGS. 10A and 10B, an insulating cap layer 190 can be formed over the light emitting diodes (10B, 10G, 10R), and can be optionally planarized. Contact via structures 192 contacting various nodes of the light emitting diodes (10B, 10G, 10R) can be formed through the insulating cap layer 190. For example, the contact via structures 192 can include first contact via structures contacting a transparent conductive layer 180 of a respective one of the first light emitting diodes 10B, second contact via structures contacting a transparent conductive layer 180 of a respective one of the second light emitting diodes 10G, and third contact via structures contacting an upper electrode 430 of a respective one of the third light emitting diodes 10R. Further, cathode contact via structures (not shown) that contacts the n-doped compound semiconductor substrate layer 26 can be formed through the insulating cap layer 190.

Suitable metal interconnect structures (not shown) can be formed above the insulating cap layer 190 in a manner that does not obstruct the path of emitted light from the light emitting diodes (10B, 10G, 10R). For example, a first light emission area 33B from which light from the first light emitting diode 10B is emitted, a second light emission area 33G from which light from the second light emitting diode 10G is emitted, and a third light emission area 33R from which light from the third light emitting diode 10R is emitted can be free of any overlying metal interconnect structures to allow unhindered emission of light from each of the light emitting diodes (10B, 10G, 10R).

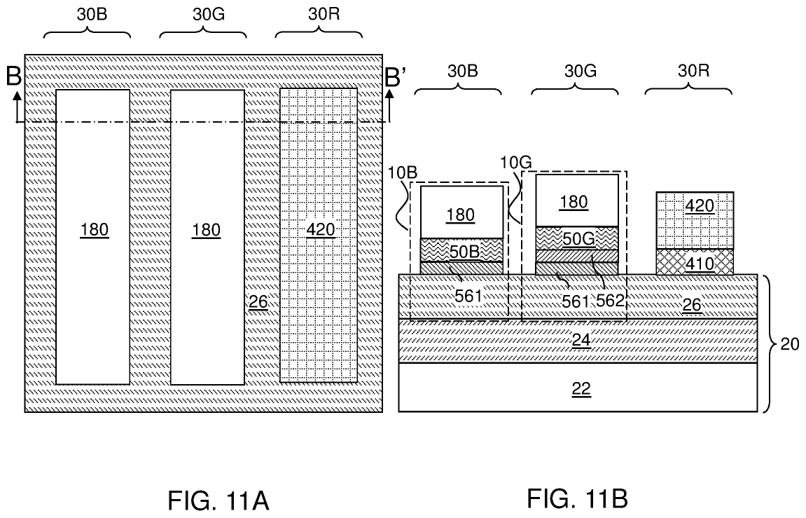

Referring to FIGS. 11A and 11B, a first configuration of a second exemplary structure according to a second embodiment of the present disclosure can be derived from the first exemplary structure illustrated in FIGS. 9A and 9B by deferring formation of the upper electrode 430. Specifically, a material layer stack including, from bottom to top, a metallic material layer and an organic light emitting material layer can be formed over the top surface of the n-doped compound semiconductor substrate layer 26, and can be patterned employing a combination of a lithographic patterning process and an etch process (which may employ an anisotropic etch process). A remaining portion of the material layer stack within the area of the third light emitting region 30R includes a lower electrode 410 and an organic light emitting material portion 420. The lower electrode 410 and the organic light emitting material portion 420 can have vertically coincident sidewalls. The horizontal cross-sectional shape of the lower electrode 410 and the organic light emitting material portion 420 can be the same.

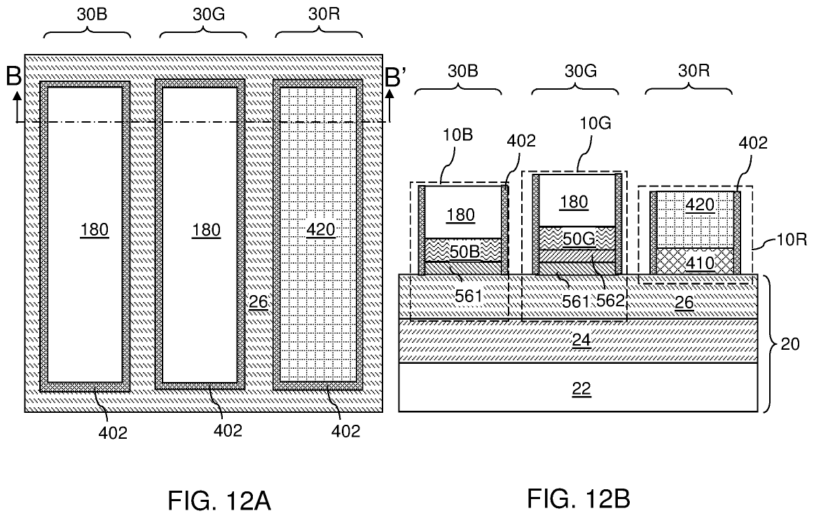

Referring to FIGS. 12A and 12B, a pixel definition layer material can be deposited and patterned to form pattern definition layer spacers. In one embodiment, the spacers comprise emission-level dielectric material spacers 402. The spacers can be formed by depositing a dielectric material, such as an optically opaque dielectric material layer over sidewalls of the lower electrode 410, over sidewalls of the organic light emitting material portion 420, and over a top surface of the organic light emitting material portion 420, and anisotropically etching the optically opaque dielectric material layer using a sidewall spacer etch. The anisotropic etch process etches horizontal portions of the optically opaque dielectric material layer. In this case, each remaining vertical portion of the optically opaque dielectric material layer constitutes a respective emission-level dielectric material spacer 402 that laterally surrounds a respective light emitting diode (10B, 10G, 10R).

Each of the emission-level dielectric material spacers 402 contacts a respective light-emitting element such as a first-type active region 561 of the first light emitting diode 10B, a second-type active region 562 of the second light emitting diode 10G, and an organic light emitting material portion 420 of the third light emitting diode 10R. Each emission-level dielectric material spacer 402 has a hollow rectangular or cylindrical configuration, and thus, includes an opening overlying a center region of a respective light emitting diode (10B, 10G, 10R). As such, the emission-level dielectric material spacer 402 that laterally surrounds, and contacts, the organic light emitting material portion 420 is formed with an opening that overlies the organic light emitting material portion 420.

In one aspect, the emission-level dielectric material spacers 402 includes an optically opaque dielectric material that that provides absorption of more than 80%, and/or more than 90%, such as 95% to 99.9% of visible light in the entire wavelength range of the visible light spectrum (i.e., the range from 400 nm to 800 nm). In one embodiment, the emission-level dielectric material spacers 402 comprise carbon, a polymer material, a spin-on glass, or a metal oxide material embedded in a polymer. For example, the emission-level dielectric material spacers 402 can include “black” materials, such as molybdenum oxide or other dielectric metal oxide embedded in an organic dielectric matrix material, such as silicone or a resin. The lateral thickness of each emission-level dielectric material spacers 402 can be in a range from 10 nm to 1 micron, although lesser and greater thicknesses can also be employed for each of the layers.

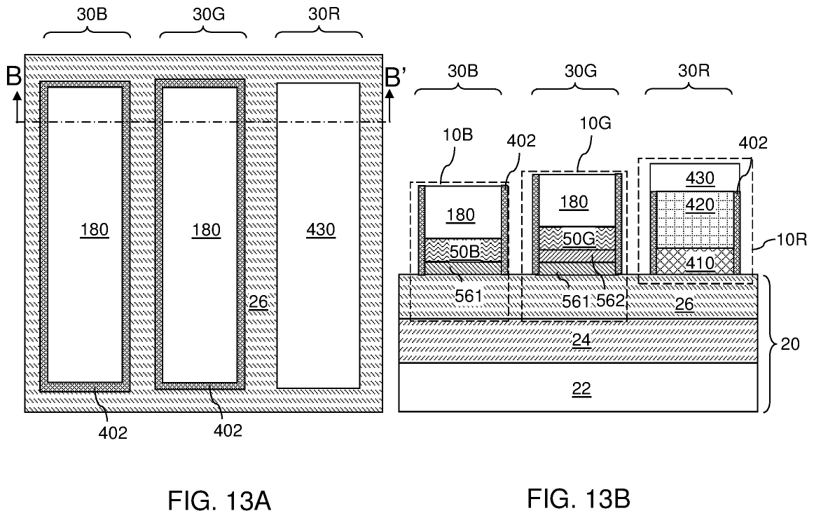

Referring to FIGS. 13A and 13B, a transparent conductive material can be deposited on the top surface of the organic light emitting material potion 420 and can be patterned to form an upper electrode 430, which can have the same material composition and the same thickness as in the first embodiment. The upper electrode 430 can be formed directly on a top surface of the underlying emission-level dielectric material spacer 402.

According to an aspect of the present disclosure, each emission-level dielectric material spacer 402 absorbs light impinging thereupon, and reduces or prevents lateral emission of light from a respective light emitting diode (10B, 10G, 10R). As such, each emission-level dielectric material spacer 402 is a pattern definition layer that defines and/or modifies a light emission pattern from each light emitting diode (10B, 10G, 10R). In the first configuration of the second exemplary structure, a pattern definition layer includes, and consists of, a respective emission-level dielectric material spacer 402 that is formed directly on all sidewalls of a respective light emitting diode (10B, 10G, 10R). The pattern definition layer for the third light emitting diode 10R can contact all sidewalls of the organic light emitting material portion 420. Each pattern definition layer, as embodied as a respective emission-level dielectric material spacer 402, includes an opaque dielectric material that laterally surrounds a light-emitting element of a respective light emitting diode (10B, 10G, 10R), and is formed with an opening that overlies the light-emitting element of the respective light emitting diode (10B, 10G, 10R).

While the emission-level dielectric material spacers 402 are illustrated in FIGS. 13A and 13B as being formed on each of the light emitting diodes (10B, 10G, 10R), embodiments are expressly contemplated in which the emission-level dielectric material spacers 402 are formed only on some of the light emitting diodes, such as only one the red light emitting diodes 10R, but not on the blue or green light emitting diodes (10B, 10G).

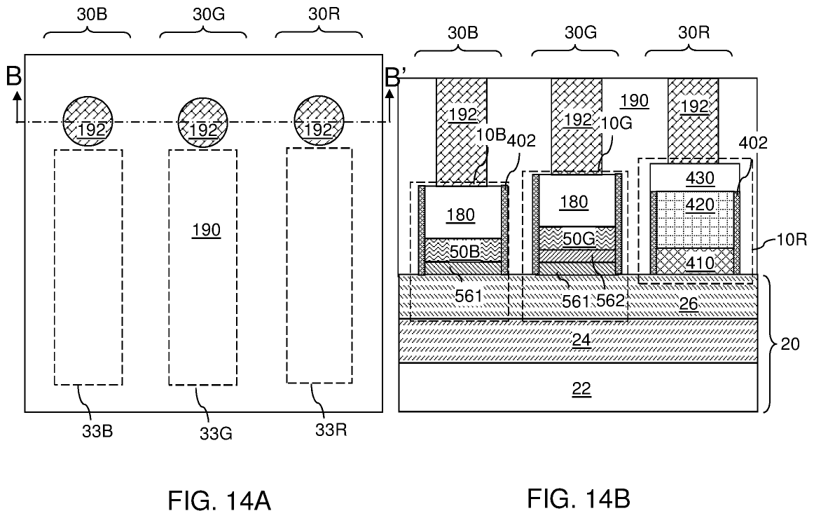

Referring to FIGS. 14A and 14B, the processing steps of FIGS. 10A and 10B can be performed to form an insulating cap layer 190 and contact via structures 192 contacting each of the light emitting diodes (10B, 10G, 10R). The light emission areas (33B, 33G, 33R) for the light emitting diodes (10B, 10G, 10R) can be defined by the inner periphery of a respective pattern definition layer, which comprises a respective one of the emission-level dielectric material spacers 402.

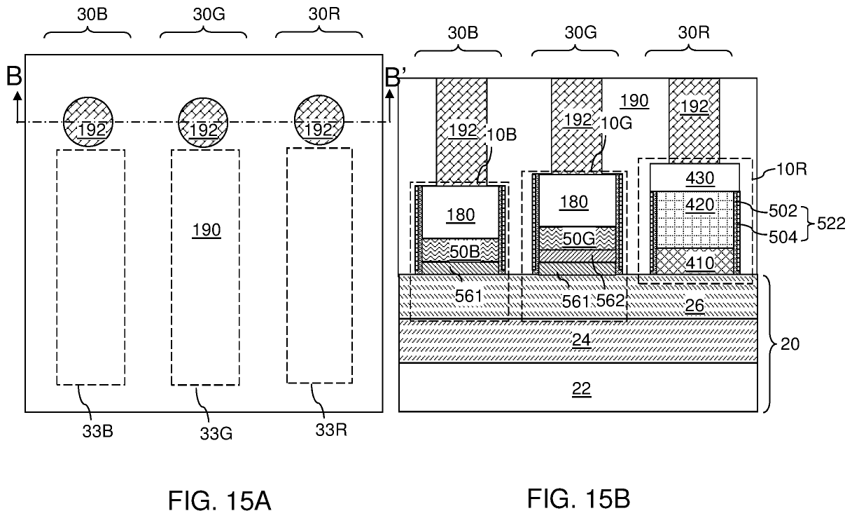

Referring to FIGS. 15A and 15B, a second configuration of the second exemplary structure of the second embodiment can be derived from the first configuration of the second exemplary structure by employing a layer stack including a combination of an optically opaque dielectric material layer and a reflective material layer in lieu of the single optically opaque dielectric material layer. Thus, a reflective material layer such as a metal layer (e.g., a silver layer, a gold layer, a copper layer, and/or an aluminum layer) can be deposited on the optically opaque dielectric material layer by a conformal or non-conformal deposition process. The thickness of the reflective material layer can be in a range from 50 nm to 200 nm, although lesser and greater thicknesses can also be employed.

The layer stack including an optically opaque dielectric material layer and the reflective material layer can be patterned by performing an anisotropic etch process. Each remaining discrete patterned portion of the optically opaque dielectric material layer constitutes an emission-level dielectric material spacer 502. Each remaining discrete patterned portion of the reflective material layer constitute a reflective material spacer 504. Each reflective material spacer 504 can contact, and laterally surround, a respective one of the emission-level dielectric material spacers 502, but does not contact the n-doped compound semiconductor substrate layer 26. Each contiguous combination of an emission-level dielectric material spacers 502 and a reflective material spacer 504 constitutes a pattern definition layer 522.

Each pattern definition layer 522 absorbs light impinging thereupon, and prevents lateral emission of light from a respective light emitting diode (10B, 10G, 10R). As such, each pattern definition layer 522 that defines and/or modifies a light emission pattern from each light emitting diode (10B, 10G, 10R). In the second configuration of the second exemplary structure, a pattern definition layer 522 includes an emission-level dielectric material spacer 502 that is formed directly on all sidewalls of a respective light emitting diode (10B, 10G, 10R), and a reflective material spacer 504 that laterally surrounds the emission-level dielectric material spacer 502. The pattern definition layer 522 for the third light emitting diode 10R can contact all sidewalls of the organic light emitting material portion 420. Each pattern definition layer 522 includes an opaque dielectric material that laterally surrounds a light-emitting element of a respective light emitting diode (10B, 10G, 10R), and is formed with an opening that overlies the light-emitting element of the respective light emitting diode (10B, 10G, 10R). The upper electrode 430 of the third light emitting diode 10R is formed directly on a top surface of the emission-level dielectric material spacer 502 and directly on a top surface of the reflective material spacer 504

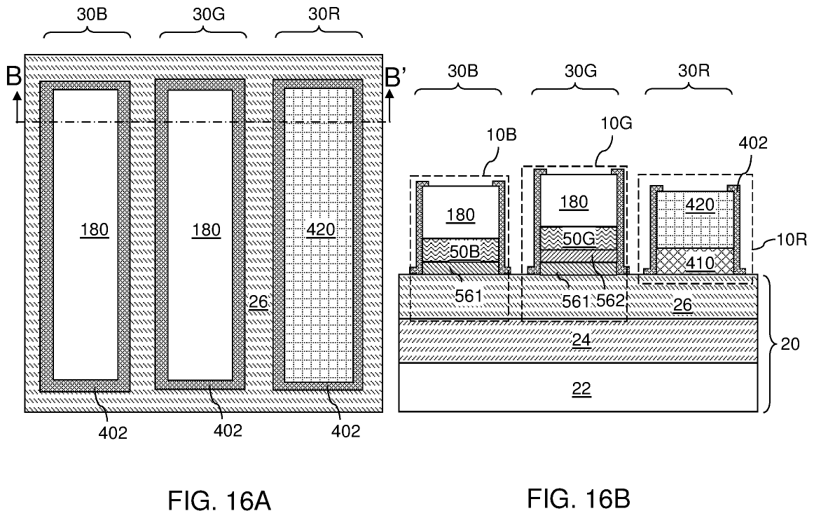

Referring to FIGS. 16A and 16B, a third configuration of the second exemplary structure according to the third embodiment of the present disclosure can be derived from the first configuration of the second exemplary structure illustrated in FIGS. 12A and 12B by employing an etch mask layer for patterning the optically opaque dielectric material layer in lieu of an anisotropic etch process that forms self-aligned emission-level dielectric material spacers 402. Specifically, the optically opaque dielectric material layer can be deposited over sidewalls of the lower electrode 410, sidewalls of the organic light emitting material portion 420, and a top surface of the organic light emitting material portion 420 of the third light emitting diode 10R and optionally over physically exposed surfaces of the first and/or second light emitting diodes (10B, 10R). Portions of the optically opaque dielectric material layer can be masked with a patterned etch mask layer such as a patterned photoresist layer. Unmasked portions of the optically opaque dielectric material layer that are not covered by the patterned etch mask layer can be etched by an etch process, which may employ an anisotropic etch process or an isotropic etch process. Each remaining portion of the optically opaque dielectric material layer constitutes an emission-level dielectric material spacer 402. In this case, the emission-level dielectric material spacers 402 may cover the periphery (e.g., edge portions) of the top surface of the organic light emitting material portion 420 of the red light emitting diode 10R. The emission-level dielectric material spacers 402 contain an opening overlying a center region of a respective light emitting diode (10B, 10G, 10R). Optionally, the emission-level dielectric material spacers 402 may also have a respective lower horizontal portion that extend outward from a bottom end of a respective vertical cylindrical portion and/or a respective upper horizontal portion that extends inward above an underlying light emitting diode (10B, 10G, 10R).

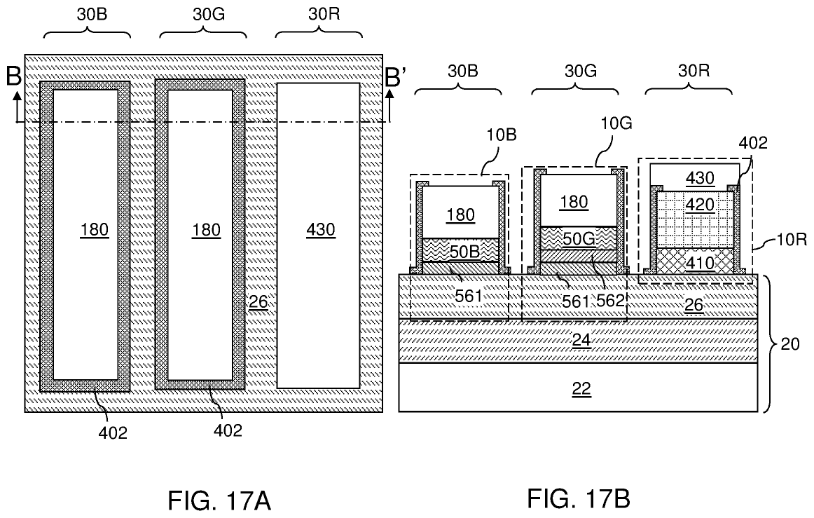

Referring to FIGS. 17A and 17B, the processing steps of FIGS. 13A and 13B can be performed to form an upper electrode 430 on top of the organic light emitting material portion 420. The upper electrode 430 is also formed on the horizontal portions of the material spacers 402 that cover the periphery (e.g., edge portions) of the top surface of the organic light emitting material portion 420.

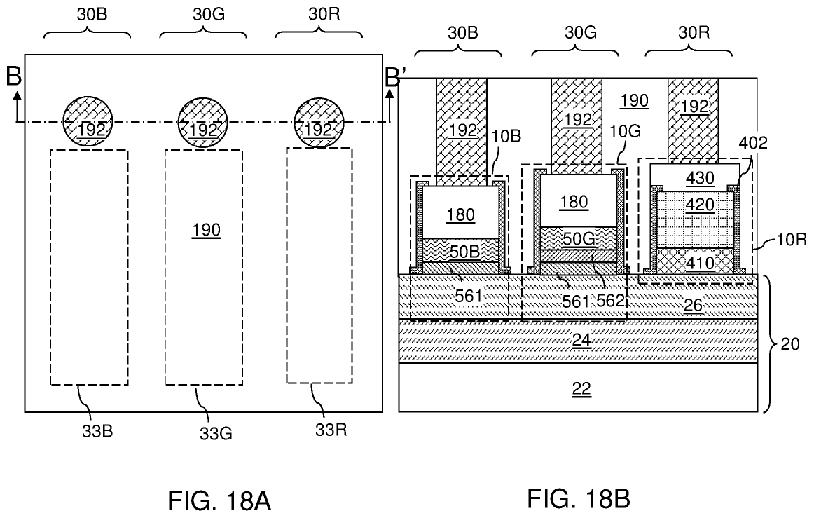

Referring to FIGS. 18A and 18B, the processing steps of FIGS. 14A and 14B can be performed to form an insulating cap layer 190 and contact via structures 192 contacting each of the light emitting diodes (10B, 10G, 10R). The light emission areas (33B, 33G, 33R) for the light emitting diodes (10B, 10G, 10R) can be defined by the inner periphery of a respective pattern definition layer, which is embodied as a respective one of the emission-level dielectric material spacers 402.

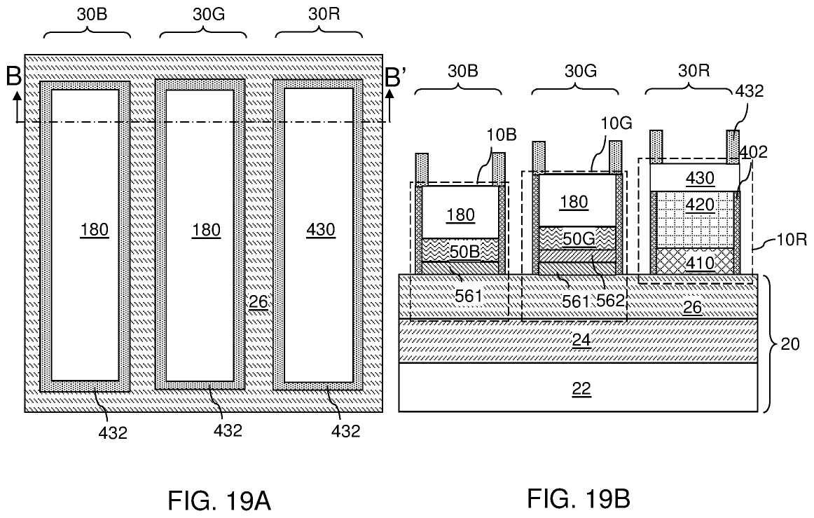

Referring to FIGS. 19A and 19B, a first configuration of a third exemplary structure according to the third embodiment of the present disclosure can be derived from the first configuration of the second exemplary structures illustrated in FIGS. 13A and 13B by forming opaque metal lines which are herein referred to as capping lines 432. The capping lines 432 are formed as capping structures for light emitting diodes (10B, 10G, 10R). The capping lines 432 are formed directly on a top surface of an underlying one of the light emitting diodes (10B, 10G, 10R). The capping lines 432 can include any opaque metal or alloy, such as silver, aluminum, copper, gold, molybdenum, tungsten or alloys thereof.

For example, the capping lines 432 can be formed by depositing an optically opaque or reflective metal or metal alloy layer over physically exposed surfaces of the light emitting diodes (10B, 10G, 10R). A photoresist layer can be applied over the layer, and can be lithographically patterned to cover peripheral areas of each of the light emitting diodes (10B, 10G, 10R) or a subset of the light emitting diodes (e.g., diode 10R). A peripheral area of the third light emitting diode 10R can be covered by a patterned portion of the photoresist layer. An etch process can be performed to etch unmasked portions of the layer. The etch process can include an anisotropic etch process (such as a reactive ion etch process) or an isotropic etch process. Each remaining portion of the layer constitutes a capping line 432.

Alternatively, the capping lines 432 may be formed by a lift-off process in which the photoresist covers at least the center portion but exposes periphery (e.g., edge portions) of the top surface of the organic, red light emitting diode 10R. The metal or metal alloy layer is deposited on the photoresist and on the exposed portion of the light emitting diode 10R. The photoresist is then lifted off with the overlying portion of the metal or metal alloy layer to form the capping lines 432.

Each capping line 432 may be formed entirely above a top surface of a respective light emitting diode (10B, 10G, 10R). In this case, a capping line 432 that overlies the light emitting diode 10R can be formed entirely above an upper electrode 430. A capping line 432 that overlies a second light emitting diode 10G can be formed entirely above a transparent conductive layer 180 of the second light emitting diode 10G. A capping line 432 that overlies a first light emitting diode 10B can be formed entirely above a transparent conductive layer 180 of the first light emitting diode 10B. Each capping line 432 can have a hollow rectangular or cylindrical configuration, and thus, includes an opening above the top surface of an underlying light emitting diode (10B, 10G, 10R). As such, the capping line 432 that overlies, and contacts, the upper electrode 430 of the third (i.e., organic red) light emitting diode 10R is formed with an opening that defines a light emission area of the third light emitting diode 10R.

Each of the emission-level dielectric material spacers 402 and the capping lines 432 functions as a pattern definition layer that defines, or modifies, a light emission pattern from a respective light emitting diode (10B, 10G, 10R). The emission-level dielectric material spacers 402 can function as lower pattern definition layers, and the capping lines 432 can function as upper pattern definition layers. The capping line 432 that overlies the third light emitting diode 10R is formed over a peripheral portion of the upper electrode 430, includes an opening that overlies a center portion of the upper electrode 430, and is formed entirely above a horizontal plane including the top surface of the upper electrode 430.

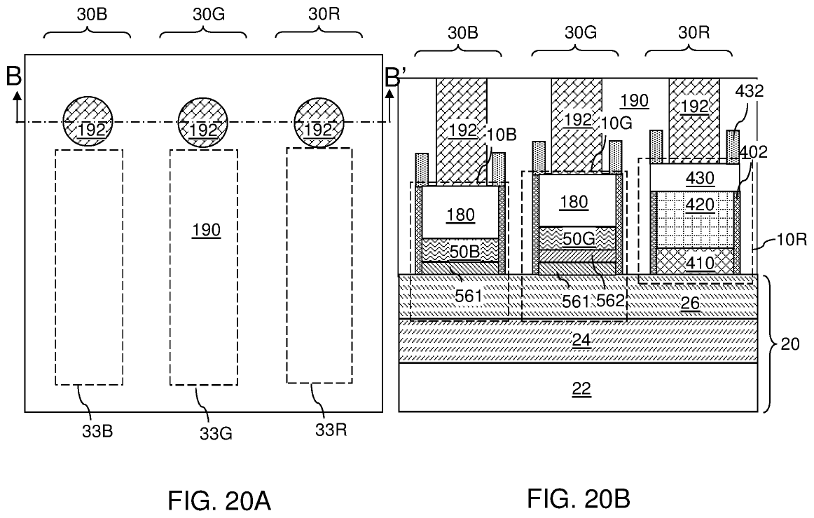

Referring to FIGS. 20A and 20B, the processing steps of FIGS. 14A and 14B can be performed to form an insulating cap layer 190 and contact via structures 192 contacting each of the light emitting diodes (10B, 10G, 10R). The light emission areas (33B, 33G, 33R) for the light emitting diodes (10B, 10G, 10R) can be defined by the inner periphery of a respective pattern definition layer, which comprises a respective one of the capping lines 432.

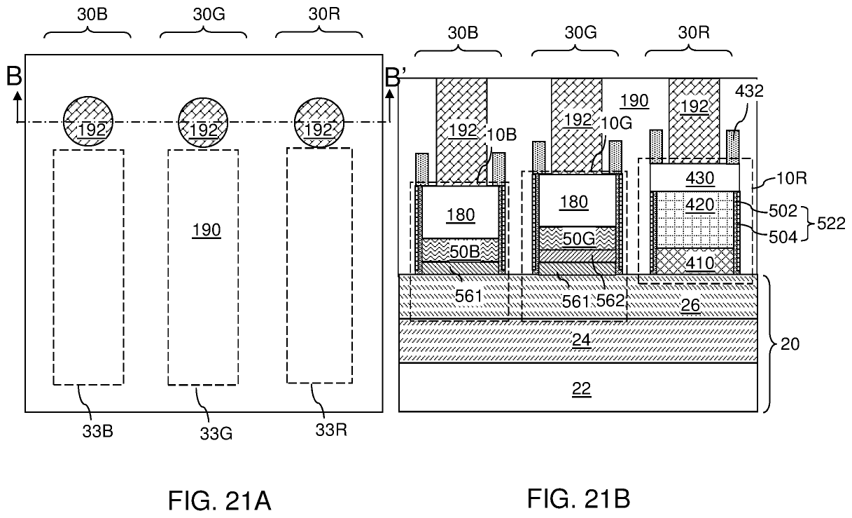

Referring to FIGS. 21A and 21B, a second configuration of the third exemplary structure can be derived from the second configuration of the second exemplary structure by performing the processing steps of FIGS. 19A, 19B, 20A, and 20B. Each contiguous combination of an emission-level dielectric material spacer 502 and a reflective material spacer 504 constitutes a lower pattern definition layer 522, and each capping lines 432 functions as an upper pattern definition layer. Each lower pattern definition layer can include a stack of an emission-level dielectric material spacer 502 and a reflective material spacer 504 that contacts, and laterally surrounds, the emission-level dielectric material spacer 502. Each upper pattern definition layer can include, and/or can consist of, a respective capping line 432.

The lower pattern definition layer 522 and the upper pattern definition layer define, and/or modify, a light emission pattern from a respective light emitting diode (10B, 10G, 10R). The capping line 432 that overlies the third light emitting diode 10R is formed over a peripheral portion of the upper electrode 430, includes an opening that overlies a center portion of the upper electrode 430, and is formed entirely above a horizontal plane including the top surface of the upper electrode 430.

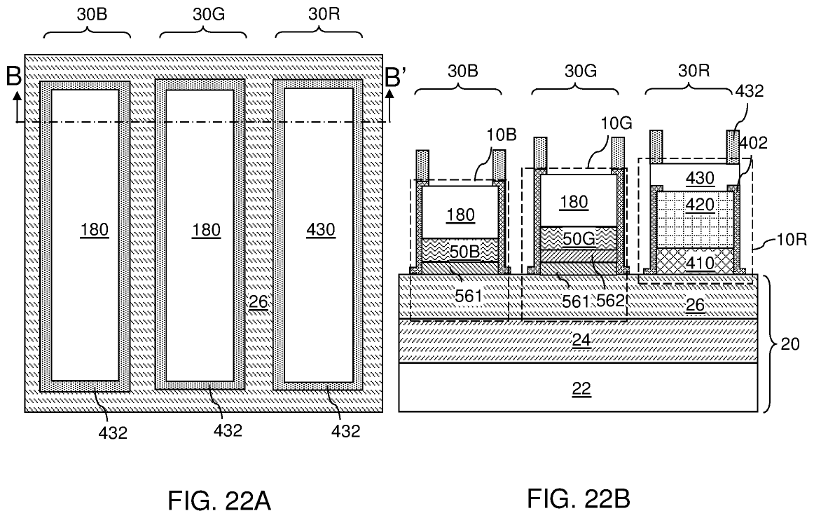

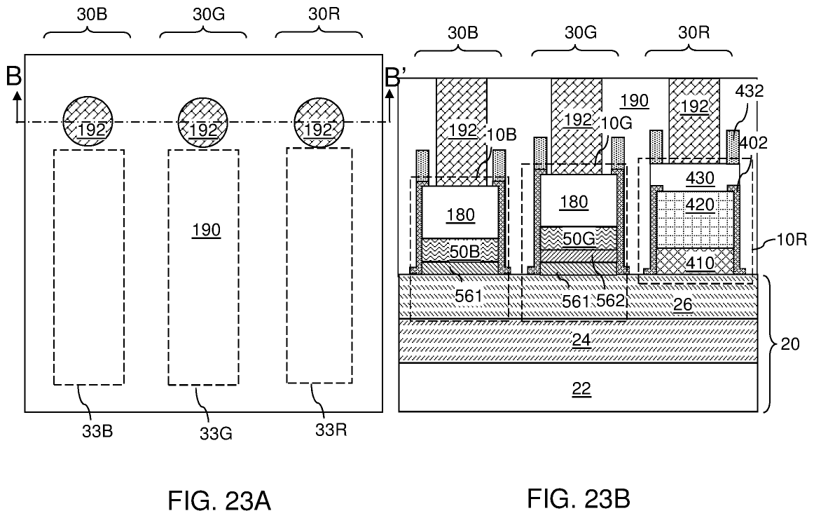

Referring to FIGS. 22A and 22B, a third configuration of the third exemplary structure according to the third embodiment of the present disclosure can be derived from the third configuration of the second exemplary structure illustrated in FIGS. 17A and 17B by performing the processing steps of FIGS. 19A and 19B. The emission-level dielectric material spacers 402 can function as lower pattern definition layers, and the capping lines 432 can function as upper pattern definition layers. The emission-level dielectric material spacer 402 can be formed by deposition and patterning of a first optically opaque dielectric material layer prior to formation of the upper electrode 430 of the third light emitting diode 10R, and the capping line 432 can be formed by deposition and patterning of a second opaque dielectric material layer after formation of the upper electrode 430 of the third light emitting diode 10R.

Each emission-level dielectric material spacer 402 constitutes a lower pattern definition layer. Each capping line 432 constitutes an upper pattern definition layer. The lower pattern definition layer and the upper pattern definition layer define, and/or modify, a light emission pattern from a respective light emitting diode (10B, 10G, 10R). The capping line 432 that overlies the third light emitting diode 10R is formed over a peripheral portion of the upper electrode 430, includes an opening that overlies a center portion of the upper electrode 430, and is formed entirely above a horizontal plane including the top surface of the upper electrode 430.

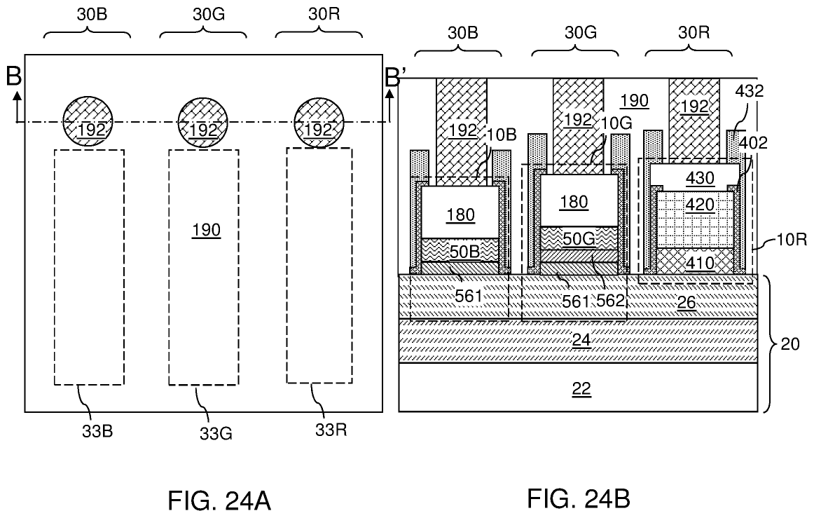

Referring to FIGS. 24A and 24B, a fourth configuration of the third exemplary structure according to the third embodiment of the present disclosure can be derived from the first, second, or third configuration of the third exemplary structure by altering the lithographic pattern to form the capping lines 432. Specifically, the outer periphery of each generally annular pattern of patterned photoresist material portions can be located outside the outer periphery of an underlying pattern definition layer (comprising an emission-level dielectric material spacer 402). In this case, the capping lines 432 can vertically extend over, and contact, outer sidewalls of the underlying emission-level dielectric material spacer 402, but not contact layer 26.

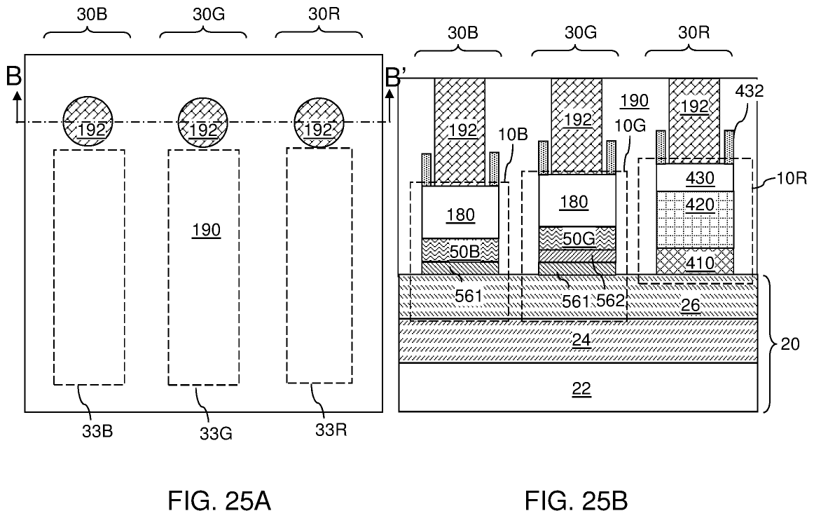

Referring to FIGS. 25A and 25B, a fifth configuration of the third exemplary structure according to the third embodiment of the present disclosure can be derived from the fourth configuration of the third exemplary structure by omitting formation of the emission-level dielectric material spacer 402 or the lower pattern definition layer 522. In this case, the capping lines 432 can be the only pattern definition layers provided in each pixel of the light emitting device. As such, the light emission areas (33B, 33G, 33R) for the light emitting diodes (10B, 10G, 10R) can be defined by the inner periphery of a respective pattern definition layer, which comprises a respective one of the capping lines 432.

Referring to all drawings and according to various embodiments of the present disclosure, a light emitting device includes a first light emitting diode 10B configured to emit light at a first peak wavelength; a second light emitting diode 10G configured to emit light at a second peak wavelength that is different from the first peak wavelength; and a third light emitting diode 10R including, from bottom to top, a lower electrode 410, an organic light emitting material portion 420, and an upper electrode 430, wherein the third light emitting diode 10R is configured to emit light at a third peak wavelength that is different from the first and second peak wavelengths, and a pattern definition layer {(402 or 522) and/or 432} including an opaque material that covers at least a portion of the organic light emitting material portion 420 and includes an opening over the organic light emitting material portion 420.

In the second embodiment, the pattern definition layer {(402 or 522) and/or 432} includes a dielectric material spacer (402 or 502) that laterally surrounds and contacts all sidewalls of the organic light emitting material portion 420. In one embodiment, the upper electrode 430 contacts an entirety of a top surface of the organic light emitting material portion 420 as illustrated in FIGS. 14B, 15B, 20B, 21B, and 25B. In one embodiment, the dielectric material spacer (402 or 502) contacts a periphery of a top surface of the organic light emitting material portion 420. In one embodiment, the upper electrode 430 contacts a top surface of the dielectric material spacer (402, 502).

In the third embodiment, pattern definition layer comprises an opaque metal capping line 432 that overlies a peripheral portion of the upper electrode 430 and includes an opening that overlies a center portion of the upper electrode 430. In one embodiment, the capping line 432 is located entirely above a horizontal plane including a top surface of the upper electrode 430. In one embodiment, the pattern definition layer {(402 or 522) and/or 432} further comprises a dielectric material spacer (402 or 522) that laterally surrounds and contacts all sidewalls of the organic light emitting material portion 420. In one embodiment, capping line 432 extends below a horizontal plane including a bottom surface of the upper electrode 430 and laterally surrounds the dielectric material spacer (402 or 502) as illustrated in FIG. 24B.

In one embodiment, the pattern definition layer 432 overlies a peripheral portion of the upper electrode 430 and includes an opening that overlies a center portion of the upper electrode 430. In one embodiment, the lower electrode 410 and the organic light emitting material portion 420 have vertically coincident sidewalls and the upper electrode 430 comprises an optically transparent material.

In one embodiment, the third peak wavelength of the third light emitting diode 10R is in a red spectral range, the first light emitting diode 10B includes a first-type inorganic active region, and the second light emitting diode 10G includes a second-type inorganic active region having a different composition than the first-type inorganic active region. In one embodiment, the first, second and third light emitting diodes (10B, 10G, 10R) comprise subpixels of a pixel of a direct view display device.

The pattern definition layer(s) (402, 522, and/or 432) of the embodiments present disclosure absorb and/or reflect light emitted from the respective light emitting diode (10B, 10G, 10R), thereby limiting and defining the lateral extent of light emission area from the respective light emitting diode (10B, 10G, 10R), and increasing the sharpness of the image formed by the light emitting device.

The preceding description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the following claims and the principles and novel features disclosed herein.

1. A light emitting device comprising:
a first light emitting diode configured to emit light at a first peak wavelength;
a second light emitting diode configured to emit light at a second peak wavelength that is different from the first peak wavelength; and
a third light emitting diode including, from bottom to top, a lower electrode, an organic light emitting material portion, and an upper electrode, wherein the third light emitting diode is configured to emit light at a third peak wavelength that is different from the first and second peak wavelengths, and
a pattern definition layer comprising an opaque material that covers at least a portion of the organic light emitting material portion and includes an opening over the organic light emitting material portion.

2. The light emitting device of claim 1, wherein the pattern definition layer comprises a dielectric material spacer that laterally surrounds and contacts all sidewalls of the organic light emitting material portion.

3. The light emitting device of claim 2, wherein the upper electrode contacts an entirety of a top surface of the organic light emitting material portion.

4. The light emitting device of claim 2, wherein the dielectric material spacer contacts a periphery of a top surface of the organic light emitting material portion.

5. The light emitting device of claim 2, wherein the pattern definition layer comprises a reflective material spacer that contacts, and laterally surrounds, the dielectric material spacer.

6. The light emitting device of claim 2, wherein the upper electrode contacts a top surface of the dielectric material spacer.

7. The light emitting device of claim 1, wherein the pattern definition layer comprises an opaque metal capping line that overlies a peripheral portion of the upper electrode and includes an opening that overlies a center portion of the upper electrode.

8. The light emitting device of claim 7, wherein the capping line is located entirely above a horizontal plane including a top surface of the upper electrode.

9. The light emitting device of claim 7, wherein the pattern definition layer further comprises a dielectric material spacer that laterally surrounds and contacts all sidewalls of the organic light emitting material portion.

10. The light emitting device of claim 9, wherein the capping line extends below a horizontal plane including a bottom surface of the upper electrode and laterally surrounds the dielectric metal spacer.

11. The light emitting device of claim 1, wherein the pattern definition layer overlies a peripheral portion of the upper electrode and includes an opening that overlies a center portion of the upper electrode.

12. The light emitting device of claim 1, wherein the lower electrode and the organic light emitting material portion have vertically coincident sidewalls, and wherein the upper electrode comprises an optically transparent material.

13. The light emitting device of claim 1, wherein:
the third peak wavelength of the third light emitting diode is in a red spectral range;
the first light emitting diode includes a first-type inorganic active region; and
the second light emitting diode includes a second-type inorganic active region having a different composition than the first-type inorganic active region.

14. The light emitting device of claim 1, wherein the first, second and third light emitting diodes comprise subpixels of a pixel of a direct view display device.

15. A method of forming a light emitting device, comprising:
forming a first light emitting diode configured to emit light at a first peak wavelength;
forming a second light emitting diode configured to emit light at a second peak wavelength that is different from the first peak wavelength; and
forming a third light emitting diode which includes, from bottom to top, a lower electrode, an organic light emitting material portion, wherein the third light emitting diode is configured to emit light at a third peak wavelength that is different from the first and second peak wavelengths,
wherein forming the third light emitting diode comprises forming a pattern definition layer comprising an opaque material that covers at least a portion of the organic light emitting material portion, and includes an opening over the organic light emitting material portion.

16. The method of claim 15, wherein the pattern definition layer comprises a dielectric material spacer that is formed directly on all sidewalls of the organic light emitting material portion.

17. The method of claim 16, wherein the dielectric material spacer is formed by depositing an optically opaque dielectric material layer over sidewalls of the lower electrode, over sidewalls of the organic light emitting material portion, and over a top surface of the organic light emitting material portion, and anisotropically etching the optically opaque dielectric material layer.

18. The method of claim 16, wherein the dielectric material spacer is formed by depositing an optically opaque dielectric material layer over sidewalls of the lower electrode, over sidewalls of the organic light emitting material portion, and over a top surface of the organic light emitting material portion, masking portions of the optically opaque dielectric material layer with a patterned etch mask layer, and etching unmasked portions of the optically opaque dielectric material layer that are not covered by the patterned etch mask layer, such that the dielectric material spacer contacts a periphery of a top surface of the organic light emitting material portion.

19. The method of claim 15, wherein the pattern definition layer comprises an opaque metal capping line that overlies a peripheral portion of the upper electrode and includes an opening that overlies a center portion of the upper electrode.

20. The method of claim 19, wherein the pattern definition layer further comprises a dielectric material spacer that laterally surrounds and contacts all sidewalls of the organic light emitting material portion.
